(19) United States
(12) Patent Application Publication
(10) Pub. No.: US 2022/0393345 A1
(43) Pub. Date: Dec. 8, 2022

(54) MATCHING CIRCUIT AND ANTENNA DEVICE

(71) Applicant: SONY GROUP CORPORATION, TOKYO (JP)

(72) Inventor: TOMOO KOBAYASHI, TOKYO (JP)

(21) Appl. No.: 17/755,577

(22) PCT Filed: Nov. 8, 2019
(86) PCT No.: PCT/JP2019/043935

§ 371 Date: May 2, 2022

(51) Int. Cl. H01Q 1/50; H01Q 5/335

(52) U.S. Cl. CPC H01Q 1/50; H01Q 5/335

(57) ABSTRACT

A matching circuit (100) according to the present disclosure is a matching circuit (100) that matches impedance of an antenna (200) used for communication in a plurality of frequency bands with that of a subsequent circuit (300) being subsequent to the antenna (200). The matching circuit (100) includes a selection circuit (110) and a bypass circuit (120). The selection circuit (110) includes a switch (SW) for making a selection from impedances corresponding to the respective frequency bands. A bypass circuit (120) establishes a bypass between the antenna (200) and the subsequent circuit (300).

### FIELD

The present disclosure relates to a matching circuit and an antenna device.

### BACKGROUND

Conventionally, as a way for matching the input impedance of an antenna with the output impedance of a wireless unit, a method for providing a matching circuit to the antenna has been known (see, Patent Literature 1, for example). Such a matching circuit includes a plurality of capacitive elements each having a different capacitance and a switch for switching between the capacitive elements. The matching circuit matches the impedance with the antenna in a plurality of frequency bands by causing the switch to switch between the capacitive elements connected to the antenna.

### CITATION LIST

### Patent Literature

Patent Literature 1: WO 2014/181569 A

### SUMMARY

### Technical Problem

As described above, a matching circuit has come to be required to match the impedance with an antenna operating across a wide band range, as the frequency band used by the antenna broadens, for example.

At the same time, with a recent increase of devices connected to the Internet of Things (IoT), devices having been conventionally not connected to the Internet have come to be provided with a communication function to connect to the Internet. Such a device capable of connecting to the Internet is sometimes referred to as an “IoT device”.

An increase in the products evolving into the IoT devices has been prominent, and IoT-compatible wearable devices such as smart watches and smart glasses have also come to be developed, as well as IoT home appliances such as televisions and refrigerators.

Because wearable devices are smaller in size than smartphones or home appliances, and have a limited footage available for the antenna implementation, there has been a demand for smaller antennas. As the size of the antenna becomes smaller, the radiation resistance of the antenna becomes lower, and a loss in the matching circuit becomes so substantial that the impact on the loss of the entire antenna device becomes no longer ignorable. Thus, a loss in the matching circuit needs to be minimized.

Therefore, the present disclosure provides a technology capable of further reducing a loss in the matching circuit.

### Solution to Problem

According to the present disclosure, a matching circuit is provided. The matching circuit is a matching circuit that matches impedance of an antenna used for communication in a plurality of frequency bands with that of a subsequent circuit being subsequent to the antenna. The matching circuit includes a selection circuit and a bypass circuit. The selection circuit includes a switch for making a selection from impedances corresponding to the respective frequency bands. A bypass circuit establishes a bypass between the antenna and the subsequent circuit.

### BRIEF DESCRIPTION OF DRAWINGS

FIG. 1 is a diagram illustrating an example of a matching circuit according to an embodiment of the present disclosure.

FIG. 2 is a diagram illustrating an exemplary configuration of a terminal device according to the embodiment of the present disclosure.

FIG. 3 is a diagram illustrating an example of a configuration of an antenna device according to a comparative example.

FIG. 4 is a diagram illustrating an example of a configuration of the antenna device according to the comparative example.

FIG. 5 is a Smith chart illustrating an example of the impedance characteristics of an antenna.

FIG. 6 is a Smith chart illustrating an example of the impedance characteristics of a switching circuit.

FIG. 7 is a diagram illustrating an equivalent circuit of the antenna device including the matching circuit 100 illustrated in FIG. 1.

FIG. 8 is a graph illustrating antenna characteristic simulation results of the antenna device according to the embodiment of the present disclosure.

FIG. 9 is a diagram illustrating the antenna device used in the simulation.

FIG. 10 is a diagram illustrating the antenna device used in the simulation.

FIG. 11 is a graph illustrating radiation characteristic simulation results of the antenna device.

FIG. 12 is a table indicating the combinations of the states of switches SW in the terminal device illustrated in FIG. 2.

FIG. 13 is a graph illustrating radiation characteristic simulation results of the antenna device according to the embodiment of the present disclosure.

FIG. 14 is a diagram illustrating an exemplary configuration of an antenna device according to a modification of the embodiment of the present disclosure.

FIG. 15 is an explanatory diagram illustrating an example of an external view of a wearable device.

### DESCRIPTION OF EMBODIMENTS

A preferred embodiment of the present disclosure will now be described in detail with reference to the accompanying drawings. In the present specification and in the drawings, the elements having substantially the same functional configurations are denoted by the same reference numerals, and redundant descriptions thereof will be omitted.

Furthermore, in the present specification and in the drawings, the elements having substantially the same functional configurations may be distinguished by the same reference numerals followed by different alphabets or numbers. For example, a plurality of elements having substantially the same functional configuration is distinguished, for example, as a switch SW1 and a switch SW2, as required. However, when it is not particularly necessary to distinguish the elements having substantially the same functional configuration, such elements will be given only the same reference numeral. For example, when it is not necessary to particularly distinguish the switch SW1 and the switch SW2, they are simply referred to as the switches SW.

The description will be given in the following order.
1. Overview of Matching Circuit
2. Exemplary Configuration of Wireless Communication Device
3. Study on Antenna Device Characteristics
4. Technical Features
5. Antenna Characteristic Simulation Results
6. Modification
7. Application Example
8. Summary
9. Supplement

<1. Overview of Matching Circuit>

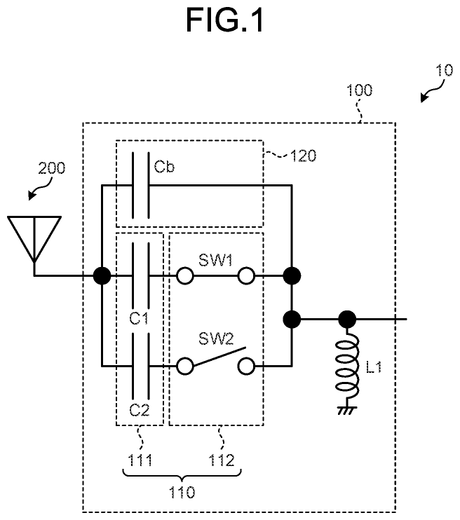

An overview of a matching circuit according to an embodiment of the present disclosure will now be given with reference to FIG. 1. FIG. 1 is a diagram illustrating an example of the matching circuit according to the embodiment of the present disclosure.

As illustrated in FIG. 1, this matching circuit 100 according to the embodiment includes a selection circuit 110, a bypass circuit 120, and an inductor L1, and has one end connected to an antenna 200 and the other end connected to a subsequent circuit such as an amplifier (not illustrated). The matching circuit 100 is disposed to match the input impedance of the antenna 200 with the output impedance of the subsequent circuit. Hereinafter, the matching circuit 100 and the antenna 200 are also collectively referred to as an antenna device 10.

The selection circuit 110 selects the impedance for the matching, based on a frequency band used by the antenna 200 in the communication. The selection circuit 110 includes a capacitor circuit 111 and a switching circuit 112.

The capacitor circuit 111 includes capacitors C1 and C2. The capacitors C1 and C2 are connected in parallel. The switching circuit 112 includes switches SW1 and SW2 that are serially connected to the capacitors C1 and C2, respectively. The selection circuit 110 switches the on/off states of the switches SW1 and SW2 so as to select the capacitor C1 or C2 that is to be connected to the subsequent circuit (for example, a wireless unit). As a result, the impedance of the selection circuit 110 is changed, and the impedance for the matching can be selected based on the operating frequency band.

The numbers of the capacitors C and the switches SW are not limited to two, and may be one or three or more as long as the impedance of the matching circuit 100 can be changed.

When the radiation resistance of the antenna 200 is low, e.g., several Ω or so, the loss owning to the resistance component of the switching circuit 112 is no longer ignorable, and the loss in the antenna device 10 including the matching circuit 100 and the antenna 200 increases.

Therefore, in the matching circuit 100 according to the embodiment of the present disclosure, in order to further reduce the loss, the bypass circuit 120 is connected in parallel with the selection circuit 110. The bypass circuit 120 is a circuit for establishing a bypass between the antenna 200 and a wireless unit (not illustrated) at a subsequent stage. The bypass circuit 120 illustrated in FIG. 1 includes a capacitor Cb. One end of the capacitor Cb is connected to the antenna 200 not via the switch SW, and the other end is connected to the wireless unit (not illustrated) at the subsequent stage.

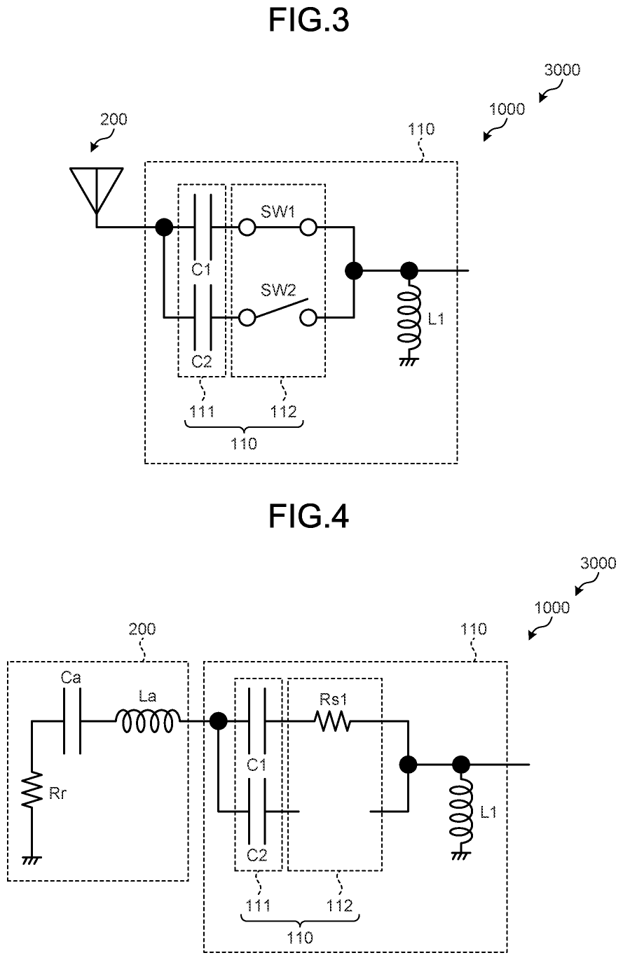

As a result, a current that is to flow into the switching circuit 112 in the selection circuit 110 can be split to the bypass circuit 120 and to the switching circuit 112, so that it is possible to reduce the current flowing into the switching circuit 112, and therefore to suppress the power consumption in the selection circuit 110. Thus, it is possible to suppress the loss in the selection circuit 110, and to further reduce the loss in the matching circuit 100. This reduction of the loss achieved by the bypass circuit 120 will be described in detail below with reference to FIGS. 3 to 7.

A terminal device 1 including such matching circuit 100 will now be described.

<2. Exemplary Configuration of Wireless Communication Device>

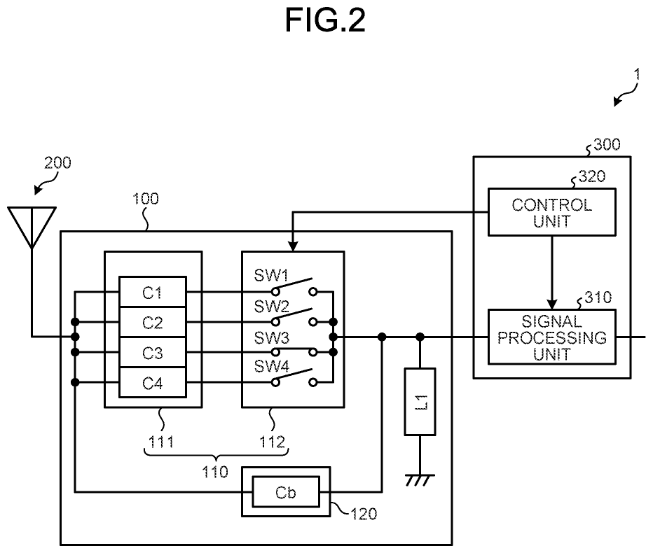

FIG. 2 is a diagram illustrating an exemplary configuration of the terminal device 1 according to the embodiment of the present disclosure. The terminal device 1 includes the matching circuit 100, the antenna 200, and a wireless communication unit 300. Hereinafter, the terminal device 1 will be described to be used in a wearable device capable of establishing cellular communication, for example.

The antenna 200 radiates a signal output from the wireless communication unit 300 to the space as a radio wave. The antenna 200 also converts a radio wave from the space into a signal, and outputs the signal to the wireless communication unit 300. The antenna 200 resonates in a plurality of frequency bands that are used for cellular communication. The antenna 200 is, for example, an inverted-L antenna.

The matching circuit 100 is a circuit for matching the input impedance of the antenna 200 with the output impedance of the wireless communication unit 300. The matching circuit 100 includes the selection circuit 110, the bypass circuit 120, and the inductor L1.

The selection circuit 110 includes a capacitor circuit 111 having one or more capacitors Cn (n=4 in the example in FIG. 2) and the switching circuit 112 having one or more switches SWn (n=4 in the example in FIG. 2). The capacitors C1 and C4 are connected in parallel. The switches SW1 to SW4 are serially connected to the capacitors C1 to C4, respectively, and switch the connection between the capacitors C1 to C4 and the wireless communication unit 300.

The bypass circuit 120 has one end connected to the antenna 200 and the other end connected to the wireless communication unit 300, and establishes a bypass between the antenna 200 and the wireless communication unit 300. The bypass circuit 120 includes the capacitor Cb. The capacitor Cb is connected in parallel with the capacitors C1 to C4 in the capacitor circuit 111. The bypass circuit 120 does not have any switch, and the capacitor Cb establishes a bypass between the antenna 200 and the wireless communication unit 300, regardless of the open or closed states of the switches SW1 to SW4.

The inductor L1 has one end connected to the selection circuit 110, and has the other end grounded. The inductor L1 is what is called a shunt inductor.

The wireless communication unit 300 communicates with other communication devices via the antenna 200. The wireless communication unit 300 includes a signal processing unit 310 and a control unit 320.

The signal processing unit 310 generates a transmission signal by modulating data to be transmitted using a predetermined modulation method, for example, and transmits the transmission signal to another communication device via the antenna 200. The signal processing unit 310 also acquires a reception result of a signal transmitted from another communication device via the antenna 200, and demodulates the data transmitted from the other communication device by performing demodulation processing to the reception result.

The control unit 320 controls the communication with other communication devices by controlling the operations of the units included in the wireless communication unit 300 and the matching circuit 100. For example, the control unit 320 controls the operation of the signal processing unit 310 so as to transmit desired data to another communication device. The control unit 320 also controls the operation of the signal processing unit 310 so as to demodulate the data received from another communication device.

In addition, the control unit 320 controls the switching circuit 112 in the matching circuit 100 so that the matching circuit 100 is set to a desired impedance. The control unit 320 selects the impedance of the matching circuit 100 based on the frequency band used by the wireless communication unit 300 in the communication. The control unit 320 switches the on/off states of the switches SW1 to SW4 in the switching circuit 112 to switch to the impedance selected by the matching circuit 100, by controlling the switches SW1 to SW4.

<3. Study on Antenna Device Characteristics>

A comparative example of the antenna device 10 and then its technical problem will now be described.

As mentioned above, because the terminal device 1 is a very small device used in a wearable device, an ultra-small antenna is also required as the antenna 200 mounted on the terminal device 1. In the embodiment of the present disclosure, an example that uses an inverted-L antenna as the ultra-small antenna 200 will be described.

When an inverted L-shaped antenna is used as the antenna 200, the antenna has a low profile from its base plate and exhibits a low radiation resistance. Thus, it is difficult to match 50Ω. In particular, when the antenna is used in a wearable device, the size of the ground where the antenna 200 is installed also becomes very small, e.g., about a few centimeters, so that the radiation resistance becomes even lower. Thus, it becomes more difficult to match 50Ω.

Therefore, in order to achieve matching between the antenna 200 and the wireless communication unit 300, a matching circuit is generally provided between the antenna 200 and the wireless communication unit 300.

### COMPARATIVE EXAMPLE

To facilitate understanding of the features of the matching circuit 100 according to the embodiment of the present disclosure, an example of an antenna device including a matching circuit will now be described as a comparative example. FIGS. 3 and 4 are diagrams illustrating an example of a configuration of the antenna device according to the comparative example. In the description below, in order to distinguish the antenna device according to the comparative example illustrated in FIGS. 3 and 4 from the antenna device 10 according to the embodiment of the present disclosure, the former antenna device is also referred to as an “antenna device 3000” for convenience.

As illustrated in FIG. 3, the antenna device 3000 includes an antenna 200 and a matching circuit 1000. The matching circuit 1000 included in the antenna device 3000 illustrated in FIG. 3 has the same configuration as the matching circuit 100 illustrated in FIG. 1, except that the bypass circuit is not provided.

In the description below, to simplify the description, it is assumed that the number of capacitors in the capacitor circuit 111 and the number of switches in the switching circuit 112 are both two, unless otherwise specified. Furthermore, in the description below, it is also assumed that the switch SW1 is in the on state and the switch SW2 is in the off state.

FIG. 4 is a diagram illustrating an equivalent circuit of the antenna device 3000 illustrated in FIG. 3. As illustrated in FIG. 4, the antenna 200 is represented by a radiation resistance Rr, a capacitor Ca, and an inductor La. In addition, because the switch SW1 is in the on state, a parasitic resistance Rs1 is generated in the switch SW1 between the capacitor C1 and the inductor L1. Because the switch SW2 is in the off state, the circuit between the capacitor C2 and the inductor L1 is open.

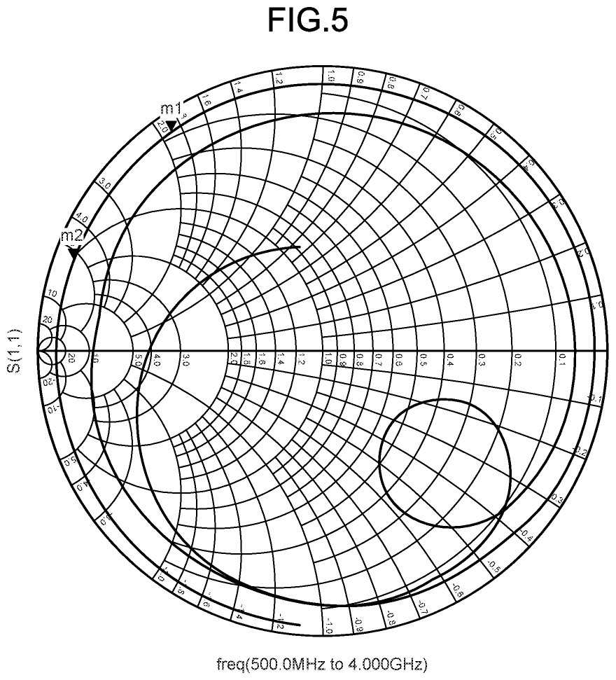

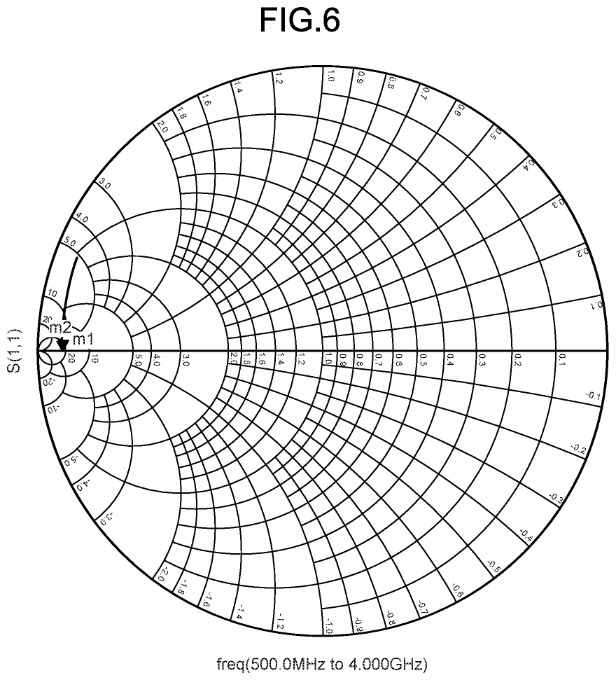

In the antenna device 3000, the on/off states of the switches SW1 and SW2 are switched so that the antenna 200 resonates at a plurality of frequencies. Impedance characteristics of the antenna 200 and the switching circuit 112 will now be described with reference to FIGS. 5 and 6. FIG. 5 is a Smith chart illustrating an example of the impedance characteristics of the antenna 200. FIG. 6 is a Smith chart illustrating an example of the impedance characteristics of the switching circuit 112.

FIG. 5 illustrates the impedance characteristics of the antenna 200 across 500 MHz to 4 GHz. For example, m1 in FIG. 5 indicates the impedance of the antenna 200 at an operating frequency of 897.6 MHz. At this time, the impedance of the antenna 200 is “2.2Ω+j0.5Ω”, and S(1, 1) is “0.934/124.835”.

In addition, m2 in FIG. 5 indicates the impedance of the antenna 200 at an operating frequency of 837.4 MHz. At this time, the impedance of the antenna 200 is “1.75Ω+j8.8Ω”, and S(1, 1) is “0.935/160.058”.

FIG. 6 illustrates the impedance characteristics of the switching circuit 112 across 500 MHz to 4 GHz. For example, m1 in FIG. 6 indicates the impedance of the switching circuit 112 at an operating frequency of 897.6 MHz. At this time, the impedance of the switching circuit 112 is “2.15Ω+j0.45Ω”, and S(1, 1) is “0.918/178.808”.

In addition, m2 indicates the impedance of the switching circuit 112 at an operating frequency of 837.4 MHz. At this time, the impedance of the switching circuit 112 is “2.1Ω+j0.45Ω”, and S(1, 1) is “0.919/179.014”.

As described above, when a small inverted-L antenna is used as the antenna 200, because the antenna 200 exhibits a low radiation resistance close to the parasitic resistance of the switching circuit 112, the loss owning to the parasitic resistance has a great impact on the loss of the antenna device 3000.

A loss given by the parasitic resistance to the antenna device 3000 will now be described specifically. As illustrated in FIG. 4, it is assumed that the entire power Pin input to the switching circuit 112 is consumed by the radiation resistance Rr of the antenna 200 and the parasitic resistance Rs1 of the switch SW1. At this time, the power Pr radiated from the radiation resistance Rr of antenna 200 is expressed by the following Equation (1).

$$\begin{matrix}[ Math . 1 ] & \\ {P}_{r} = 10 log ( \frac{Rr \times I {1}^{2}}{Rr \times I {1}^{2} + {R}_{s 1} \times I {1}^{2}} ) & ( 1 )\end{matrix}$$

Note that, I1 denotes a current input to the switching circuit 112.

It is assumed herein that the resistance of the antenna 200 and that of the switching circuit 112 are Rr=1.75Ω and Rs1=2.1Ω, respectively. By substituting “Rr=1.75Ω, Rs1=2.1Ω” into Equation (1), the power Pr can be calculated as Pr=−3.4 dB.

As described above, the switching circuit 112 introduces a loss of −3.4 dB to the antenna device 3000.

As described above, downsizing the antenna 200 results in a technical problem that the impact of the loss in the switching circuit 112 increases, and the radiation power Pr drops significantly. To address this issue, the present disclosure discloses a technology that can reduce the loss in the switching circuit 112.

<4. Technical Features>

Technical features of the terminal device 1 according to the embodiment of the present disclosure will now be described by placing a particular focus on the configuration of the antenna device 10.

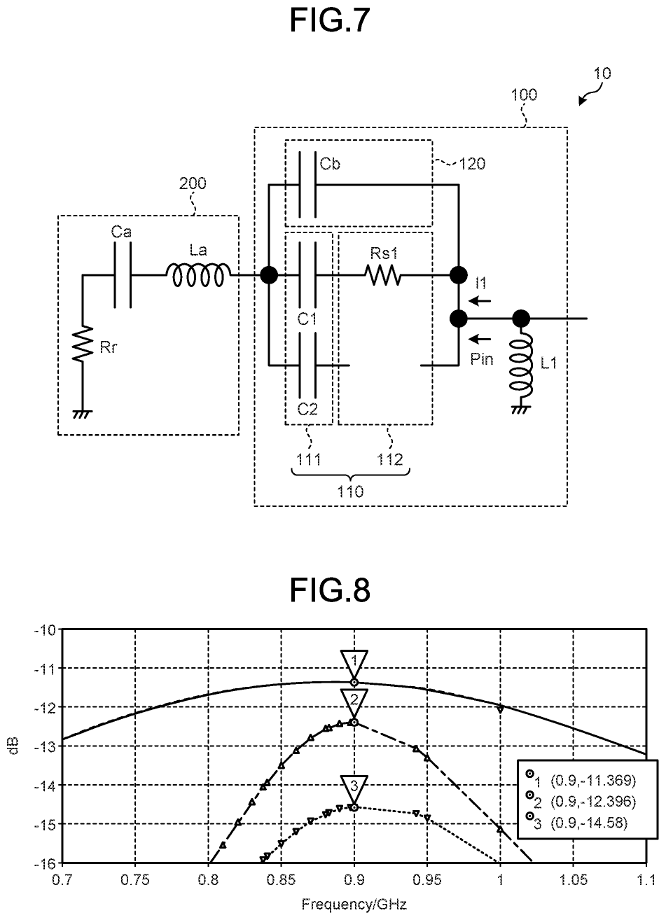

FIG. 7 is a diagram illustrating an equivalent circuit of the antenna device 10 including the matching circuit 100 illustrated in FIG. 1. The equivalent circuit illustrated in FIG. 7 has the same configuration as the antenna device 3000 illustrated in FIG. 4, except that the bypass circuit 120 is included.

As illustrated in FIG. 7, the antenna device 10 includes the capacitor Cb connected in parallel with the capacitors C1 and C2. The capacitor Cb is a component of the bypass circuit 120.

As described above, by providing the capacitor Cb to the antenna device 10 as the bypass circuit 120, the current that is to flow into the switch SW1 is split between the capacitor Cb and the switch SW1. Thus, the current flowing into the switch SW1 is reduced and the power consumed by the switch SW1 is also reduced, compared with the example in which the capacitor Cb is not provided. As a result, it is possible to reduce the loss in the antenna device 10.

Specifically, with the capacitor Cb added, the power Prs1 consumed by the parasitic resistance Rs1 of the switch SW1 is expressed by the following Equations (2) to (4).

$$\begin{matrix}[ Math . 2 ] & \\ {Pr}_{s 1} = {R}_{s 1} \times {( \frac{Z 2}{Z 1 + Z 2} \times I 1 )}^{2} & ( 2 ) \\ Z 1 = \sqrt{{R}_{s 1}^{2} + {( - \frac{1}{wC 1} )}^{2}} & ( 3 )\end{matrix}$$

Note that, Z1 denotes a combined impedance of those of the parasitic resistance Rs1 of the switch SW1 and the capacitor C1. In addition, Z2 denotes the impedance of the capacitor Cb.

Assuming that the radiation resistance Rr of the antenna 200 is Rr=1.75Ω, the parasitic resistance Rs1 of the switch SW1 is Rs1=2.1Ω, the capacitor Cb is Cb=3.7 pF, the capacitor C1 is 3 pF, and the operating frequency f of the antenna device 10 is f=900 MHz, Z1=61.1Ω and Z2=47.8Ω are obtained. Thus, the power Prs1 consumed by the parasitic resistance Rs1 of the switch SW1 is Prs=0.19Rs1×I12, and it can be seen that the parasitic resistance Rs1 of the switch SW1 is equivalently 0.19 times smaller than when the capacitor Cb is not provided.

With this result, when the power Pr radiated from the radiation resistance Rr of the antenna 200 is calculated based on Equation (1), Pr=−0.89 dB is obtained, as indicated below.

$$[ Math . 3 ] \\ Pr = 10 log ( \frac{Rr \times I {1}^{2}}{Rr \times I {1}^{2} + 0.19 {R}_{s 1} \times I {1}^{2}} ) = - 0.89 [ dB ]$$

As described above, by providing the bypass circuit 120 to the antenna device 10, the loss of the antenna device 10 can be improved from −3.4 dB to −0.89 dB, that is, improved by 2.5 dB.

<5. Antenna Characteristic Simulation Results>

A summary of some antenna characteristic simulation results of the antenna device 10 according to the embodiment of the present disclosure will be given below.

(Radiation Characteristic Simulation Results)

Radiation characteristic simulations have been carried out for the antenna device not provided with the switching circuit 112 (hereinafter, also referred to as an antenna device 4000), the antenna device 3000 not provided with the bypass circuit, and the antenna device 10 according to the embodiment of the present disclosure.

FIG. 8 is a graph illustrating the radiation characteristic simulation results of the antenna devices 10, 3000, and 4000. In FIG. 8, the vertical axis represents efficiency, and the horizontal axis represents frequency. In FIG. 8, the simulation result of the antenna device 4000 is indicated in a solid line. The simulation result of the antenna device 3000 is indicated in a dotted line. The simulation result of the antenna device is indicated in a dashed line.

Being provided with the matching circuit, the antenna device 4000 performs matching with the antenna 200. The matching circuit in the antenna device 4000 includes the inductor L1 and the capacitor C1 in the capacitor circuit 111, but does not include the switching circuit 112, and therefore, there is no loss introduced by the switching circuit 112.

By contrast, the antenna device 3000 is provided with the matching circuit 1000 illustrated in FIG. 3. The matching circuit 1000 includes the capacitor circuit 111 and the switching circuit 112, but not the bypass circuit 120. In this configuration, because a loss is introduced by the switching circuit 112, the radiation efficiency of the antenna device 3000 drops by about −3.2 dB, compared with that with the antenna device 4000, as illustrated in FIG. 8.

The antenna device 10 according to the embodiment of the present disclosure is provided with the matching circuit 100 illustrated in FIG. 1. The matching circuit 100 includes the bypass circuit 120, in addition to the selection circuit 110. In this configuration, a loss is introduced by the switching circuit 112, but is smaller than that in the antenna device 3000 not including the bypass circuit 120. Thus, as illustrated in FIG. 8, a drop in the radiation efficiency of the antenna device 10 remains about −1 dB, compared with that in the antenna device 4000.

The simulations were carried out under an assumption that, for the antenna devices 10 and 3000, the switch SW1 of the switching circuit 112 is in the on state, and the capacitor C1 is connected to the wireless communication unit 300 (see FIG. 2) at the subsequent stage. In addition, the simulations were carried out by setting the capacitor Cb as Cb=3.7 pF, the capacitor C1 as C1=3 pF, the inductor L1 as L1=3.9 nH, and the parasitic resistance Rs1 of the switch SW1 as Rs1=2.1Ω.

As described above, because the antenna device 10 according to the embodiment of the present disclosure includes the bypass circuit 120, it is possible to improve the radiation efficiency and to reduce the loss.

(Simulation Results in Two Frequency Bands)

A description of how the matching circuit 100 can match the impedance of the antenna 200 in a plurality of frequency bands will now be given.

As mentioned above, the terminal device 1 according to the embodiment of the present disclosure is used in, for example, a wearable device capable of establishing cellular communication. In the cellular communication, for example, different frequency bands (bands) are allocated depending on the mobile network operators (MNOs), countries, and regions. Therefore, in order to support the communication using different MNOs or in different countries, for example, it is preferable for the terminal device 1 to be capable of performing the communication in a plurality of frequency bands. In other words, it is preferable for the antenna device 10 of the terminal device 1 to be capable of operating in a plurality of frequency bands, and for the matching circuit 100 to be capable of matching the impedance of the antenna 200 in a plurality of frequency bands.

Therefore, in the matching circuit 100 according to the embodiment of the present disclosure, the impedance of the matching circuit 100 is selected by the selection circuit 110 so as to be matched with the impedance of the antenna 200 in a plurality of frequency bands.

At this time, for example, the selection circuit 110 can also select the impedance of the capacitor Cb in the bypass circuit 120, as one of the capacitive elements included in the capacitor circuit 111. Specifically, when the switching circuit 112 switches all of the switches SW to the off states, the capacitor Cb becomes connected to the subsequent circuit (the wireless communication unit 300 in FIG. 2), and the capacitors C in the selection circuit 110 is disconnected from the wireless communication unit 300. When at least one of the switches SW in the switching circuit 112 is switched to the on state, the capacitor Cb and the capacitor C that is serially connected to the switch SW in the on state become connected to the wireless communication unit 300.

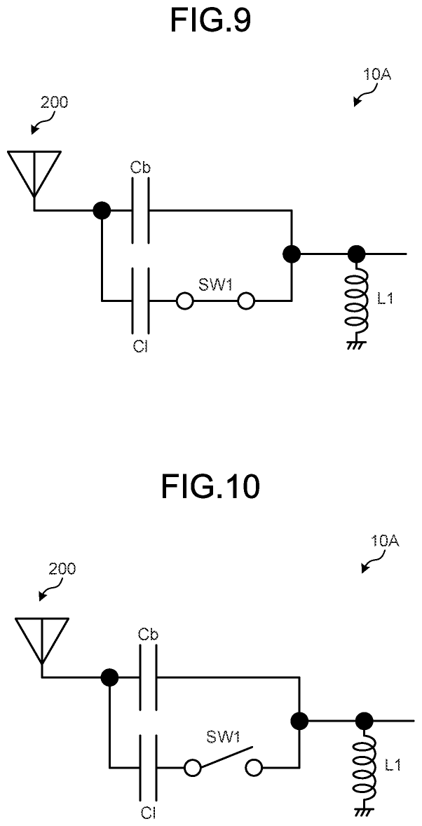

As described above, by switching the connection to the switches SW, including the configuration in which all the switches SW of the switching circuit 112 are switched off, a plurality of impedances can be selected for the matching circuit 100. As a result, the matching circuit 100 can match the impedance of the antenna 200 in a plurality of frequency bands. This point will now be described with reference to FIGS. 9 to 11.

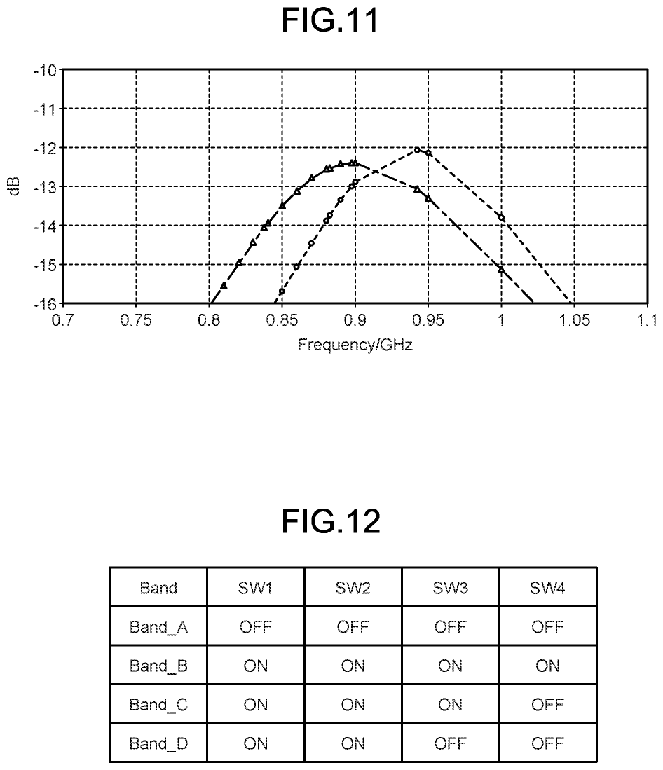

FIGS. 9 and 10 are diagrams illustrating the antenna device used in the simulations (hereinafter, also referred to as an antenna device 10A). FIG. 11 is a graph illustrating the simulation results using the antenna device 10A.

The antenna device 10A illustrated in FIGS. 9 and 10 is a device in which a part of the antenna device 10 illustrated in FIG. 1 is omitted to simplify the description. The antenna device 10A has the same configuration as the antenna device illustrated in FIG. 1, except that the selection circuit 110 includes the one capacitor C1 and the one switch SW1, but does not include the capacitor C2 and the switch SW2. As described above, the numbers of the capacitors C and the switches SW in the selection circuit 110 may be any number equal to or more than one.

FIG. 9 is a circuit diagram illustrating the antenna device 10A with the switch SW1 switched to the on state. FIG. 10 is a circuit diagram illustrating the antenna device 10A with the switch SW1 switched to the off state. FIG. 11 illustrates radiation characteristic simulation results using the antenna device 10A illustrated in FIGS. 9 and 10. FIG. 11 is a graph illustrating the radiation characteristic simulation results of the antenna device 10A. In FIG. 11, the vertical axis represents efficiency, and the horizontal axis represents frequency.

In this example, the simulations were carried out by setting the capacitor Cb as Cb=3.7 pF, the capacitor C1 as C1=3 pF, the inductor L1 as L1=3.9 nH, and the parasitic resistance Rs1 of the switch SW1 as Rs1=2.1Ω.

A graph indicated by an alternate long and short dash line in FIG. 11 is a graph illustrating the radiation characteristics of the antenna device 10A in which the switch SW1 is in the on state. As illustrated in FIG. 11, with the switch SW1 in the on state, the antenna device 10A exhibits the highest radiation characteristic near 898 MH or so.

A graph indicated by a dashed line in FIG. 11 is a graph illustrating the radiation characteristic of the antenna device 10A in which the switch SW1 is in the off state. As illustrated in FIG. 11, with the switch SW1 in the off state, the antenna device 10A exhibits the highest radiation characteristic near 942 MHz or so.

As described above, by switching the on/off state of the switch SW1 to switch the impedance of the matching circuit 100, the antenna device 10A can operate in a plurality of frequency bands.

(Simulation Results in Four Frequency Bands)

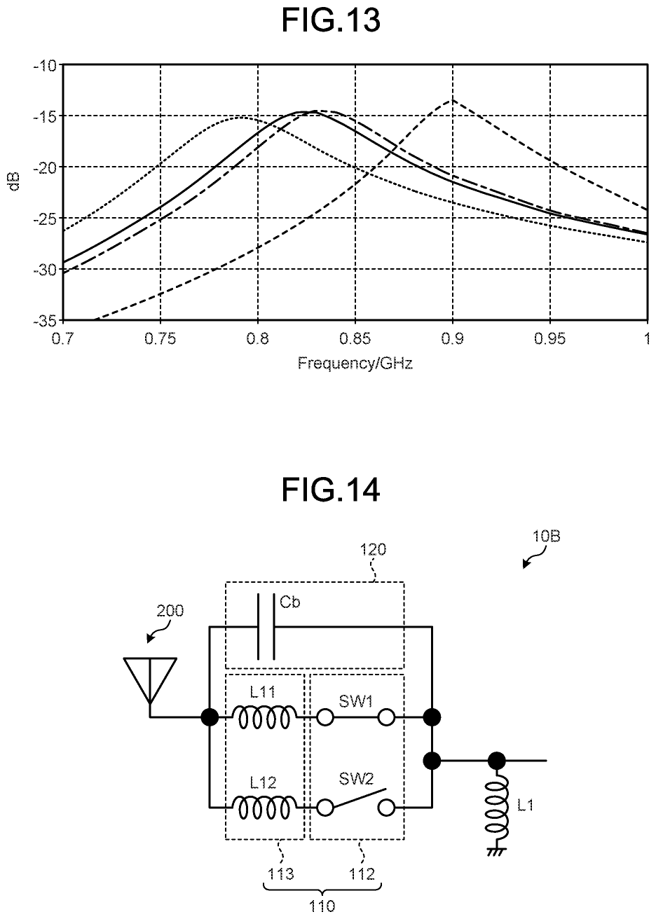

Although FIGS. 9 and 10 illustrate the antenna device 10A having the one switch SW1, as mentioned above, the number of switches SW in the matching circuit 100 may be any number equal to or more than one. The number of switches SW may be two as illustrated in FIG. 1 or four as illustrated in FIG. 2. As the number of switches SW increases, the number of frequency bands in which the antenna device 10 can operate increases. This point will now be described with reference to FIGS. 12 and 13.

FIG. 12 is a table indicating the combinations of the states of the switches SW in the terminal device 1 illustrated in FIG. 2. For example, the control unit 320 controls the states of the switches SW depending on the frequency band used in the communication, based on the table illustrated in FIG. 12. Specifically, for example, when Band_A is used in the communication, the control unit 320 switches all of the switches SW1 to SW4 to the off states. When Band_C is used in the communication, the control unit 320 switches the switches SW1 to SW3 to the on states and switches the switch SW3 to the off state. It is assumed that Band_A to Band_D illustrated in the table correspond to the bands used in LTE, for example.

FIG. 13 is a graph illustrating radiation characteristic simulation results of the antenna device 10 according to the embodiment of the present disclosure. FIG. 13 is a graph indicating the radiation characteristics of the antenna device 10 when the control unit 320 switches the switches SW based on the table illustrated in FIG. 12. The vertical axis in FIG. 13 represents efficiency, and the horizontal axis represents frequency.

In FIG. 13, the radiation characteristic of the antenna device 10 in which all of the switches SW are in the off states (Band_A) is indicated with a dashed line. The radiation characteristic of the antenna device 10 in which the switches SW1 and SW2 are in the on states and the switches SW3 and SW4 are in the off states (Band_D) is indicated with an alternate long and short dash line. The radiation characteristic of the antenna device 10 in which the switches SW1 to SW3 are in the on states and the switch SW4 is in the off state (Band_C) is indicated with a solid line. The radiation characteristic of the antenna device 10 in which all of the switches SW are in the on states (Band_B) is indicated with a dotted line.

It can be seen from the graph illustrated in FIG. 13 that the operating frequency of the antenna device 10 is switched by causing the control unit 320 to switch the states of the switches SW. As described above, the number of operating frequencies of the antenna device 10 can be increased by increasing the numbers of the switches SW and the capacitors C serially connected to the switch SW.

Thus, by being provided with the selection circuit 110 including the switches SW for selecting the impedance, the matching circuit 100 according to the embodiment of the present disclosure can match the impedance with that of the antenna 200 in a plurality of frequency bands. In addition, by providing the bypass circuit 120 for establishing a bypass between the antenna 200 and the subsequent circuit (for example, the wireless communication unit 300), it is possible to reduce the loss owning to the parasitic resistances of the switches SW, and therefore, to reduce the radiation loss of the antenna 200.

<6. Modification>

An antenna device 10B according to a modification of the embodiment of the present disclosure will now be described with reference to FIG. 14. FIG. 14 is a diagram illustrating an exemplary configuration of the antenna device 10B according to a modification of the embodiment of the present disclosure.

The antenna device 10B illustrated in FIG. 14 has the same configuration as the antenna device 10 illustrated in FIG. 1, except that an inductor circuit 113 is provided, instead of the capacitor circuit 111. The inductor circuit 113 includes inductors L11 and L12 that are connected in parallel. The inductors L11 and L12 are then serially connected to the switches SW1 and SW2 in the switching circuit 112, respectively.

As described above, it is also possible to change the impedance of the matching circuit 100 using the inductors L11 and L12, instead of the capacitors C1 and C2.

Although the configuration of the antenna device 10B including the two inductors L11 and L12 has been described herein, the number of inductors is not limited to two, and may be any number equal to or more than one. Furthermore, described herein is an example in which the antenna device 10B includes the inductors L11 and L12 instead of the capacitors C1 and C2, but the antenna device 10B may include both of the capacitor circuit 111 and the inductor circuit 113. In other words, the antenna device 10B may include one or more capacitors C and inductors L that are connected in parallel.

As described above, the selection circuit 110 only needs to include the switch SW for changing the impedance, and may take various configurations.

In addition, described above is a modification in which the capacitors C in the selection circuit 110 are replaced with the inductors, but it is also possible to replace the capacitor Cb in the bypass circuit 120 with an inductor, for example. As described above, the capacitors in the matching circuit 100 may be replaced with an inductor, as appropriate.

### 7. Application Example

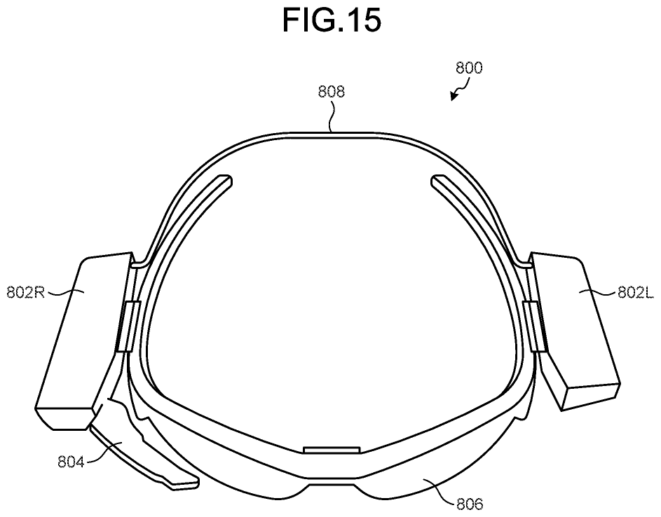

As mentioned above, the terminal device 1 is used in, for example, a wearable device capable of establishing cellular communication. Described now is an example in which the terminal device 1 is used in an eyewear-type wearable device, as an example of the wearable device. FIG. 15 is an explanatory diagram illustrating an example of an external view of the wearable device.

The wearable device 800 illustrated in FIG. 15 is an eyewear-type wearable device. The wearable device 800 includes a left main unit 802L and a right main unit 802R, a display 804, a lens 806, and a neck band 808 connecting the main units 802L and 802R. At least a part of the terminal device 1 and the like that is the technology according to the present disclosure is incorporated in the main units 802L and 802R, for example. For example, the antenna device 10 that is the technology according to the present disclosure can be installed in one of the main units 802L and 802R. In addition, the display 804 is an organic electro luminescence (EL) display, for example. Therefore, a user can see the environment surrounding the user through the lens 806, and can also see a screen displayed on the display 804 with one eye, while wearing the wearable device 800.

A main control unit (not illustrated) capable of controlling each block included in the wearable device 800 is incorporated in the main units 802L and 802R. The main control unit is implemented by hardware such as a central processing unit (CPU), a read only memory (ROM), and a random access memory (RAM). The main units 802L and 802R include a communication unit (not illustrated) capable of transmitting and receiving information to and from an external device. The communication unit is implemented by the terminal device 1 according to the embodiment of the present disclosure. The communication unit is implemented by, for example, a communication device such as the antenna 200, the wireless communication unit 300, and a port.

The wearable device 800 may also include, for example, a speaker, an earphone, a light emitting element, a vibration module, and the like for outputting various types of information to the user as sound, light, vibration, and the like. Furthermore, the wearable device 800 may also include an input unit that is implemented as a touch panel, a button, a switch, a key, a keyboard, a microphone, an image sensor, or the like, and that receives inputs of data and commands to the wearable device 800.

The wearable device 800 is not limited to the form illustrated in FIG. 15, and may be a wearable device of various types such as a head mounted display (HMD), an ear device, an anklet, a bracelet, a collar, a pad, a badge, and a piece of clothing.

<8. Summary>

As described above, with the technology of the present disclosure, the matching circuit 100 includes the selection circuit 110 having the switches SW for selecting the impedance, and the bypass circuit 120 for establishing a bypass between the antenna 200 and the circuit at the subsequent stage (for example, the wireless communication unit 300). As a result, it is possible to reduce the loss owning to the parasitic resistances of the switches SW while matching the impedance of the antenna 200 in each of a plurality of frequency bands.

<9. Supplement>

Although some preferred embodiments of the present disclosure have been described in detail with reference to the accompanying drawings, the technical scope of the present disclosure is not limited to these examples. It should be clear that those having ordinary knowledge in the technical field of the present disclosure can come up with various changes or modifications within the scope of the technical idea described in the claims, and that it should be understood that these changes and modifications naturally fall within the technical scope of the present disclosure.

Furthermore, the advantageous effects described herein are merely illustrative or exemplary, and are not restrictive. In other words, the technology according to the present disclosure can achieve other effects obvious to those skilled in the art, based on the description herein, in addition to or instead of the above-described advantageous effects.

The following configurations also fall within the technical scope of the present disclosure.

(1)

A matching circuit that matches impedance of an antenna used in communication in a plurality of frequency bands with that of a subsequent circuit being subsequent to the antenna, the matching circuit comprising:

a selection circuit that includes a switch for making a selection from impedances corresponding to the respective frequency bands; and

a bypass circuit that establishes a bypass between the antenna and the subsequent circuit.

(2)

The matching circuit according to (1), wherein the bypass circuit includes a capacitor.

(3)

The matching circuit according to (2), wherein the capacitor is connected to the antenna and the subsequent circuit not via a switch.

(4)

The matching circuit according to any one of (1) to (3), wherein

the selection circuit includes a plurality of inductors or a plurality of capacitors, and

the switch selects any of the inductors or the capacitors that are to be connected to the antenna or the subsequent circuit.

(5)

The matching circuit according to any one of (1) to (4), wherein the antenna resonates in a plurality of frequency bands that are used for cellular communication.

(6)

The matching circuit according to any one of (1) to (5), wherein the antenna is an inverted L-shaped antenna.

(7)

An antenna device comprising:

an antenna that is used in communication in a plurality of frequency bands;

a matching circuit that matches impedance of the antenna with that of a subsequent circuit being subsequent to the antenna, wherein

the matching circuit includes:

a selection circuit that includes a switch for making a selection from impedances corresponding to the respective frequency bands; and

a bypass circuit that establishes a bypass between the antenna and the subsequent circuit.

### REFERENCE SIGNS LIST

1 TERMINAL DEVICE
10, 10A ANTENNA DEVICE
100 MATCHING CIRCUIT
110 SELECTION CIRCUIT
111 CAPACITOR CIRCUIT
112 SWITCHING CIRCUIT
120 BYPASS CIRCUIT
200 ANTENNA
300 WIRELESS COMMUNICATION UNIT
310 SIGNAL PROCESSING UNIT
320 CONTROL UNIT

1. A matching circuit that matches impedance of an antenna used in communication in a plurality of frequency bands with that of a subsequent circuit being subsequent to the antenna, the matching circuit comprising:
a selection circuit that includes a switch for making a selection from impedances corresponding to the respective frequency bands; and
a bypass circuit that establishes a bypass between the antenna and the subsequent circuit.

2. The matching circuit according to claim 1, wherein the bypass circuit includes a capacitor.

3. The matching circuit according to claim 2, wherein the capacitor is connected to the antenna and the subsequent circuit not via a switch.

4. The matching circuit according to claim 3, wherein
the selection circuit includes a plurality of inductors or a plurality of capacitors, and
the switch selects any of the inductors or the capacitors that are to be connected to the antenna or the subsequent circuit.

5. The matching circuit according to claim 4, wherein the antenna resonates in a plurality of frequency bands that are used for cellular communication.

6. The matching circuit according to claim 5, wherein the antenna is an inverted L-shaped antenna.

7. An antenna device comprising:
an antenna that is used in communication in a plurality of frequency bands;
a matching circuit that matches impedance of the antenna with that of a subsequent circuit being subsequent to the antenna, wherein
the matching circuit includes:
a selection circuit that includes a switch for making a selection from impedances corresponding to the respective frequency bands; and
a bypass circuit that establishes a bypass between the antenna and the subsequent circuit.
